(19) United States
(12) Patent Application Publication
(10) Pub. No.: US 2024/0304546 A1
(43) Pub. Date: Sep. 12, 2024

(54) LOW RESISTANCE SEMICONDUCTOR INTERCONNECT STRUCTURE

(71) Applicant: INTERNATIONAL BUSINESS MACHINES CORPORATION, ARMONK, NY (US)

(72) Inventors: Oscar van der Straten, Guilderland Center, NY (US); Koichi Motoyama, Clifton Park, NY (US); Chih-Chao Yang, Glenmont, NY (US)

(21) Appl. No.: 18/179,417

(22) Filed: Mar. 7, 2023

(51) Int. Cl. H01L 23/528; H01L 21/768

(52) U.S. Cl. CPC H01L 23/5283; H01L 21/76804; H01L 21/76849; H01L 21/76883; H01L 23/53238; H01L 23/53266

(57) ABSTRACT

A structure including a homogeneous interconnect structure embedded in a dielectric layer, where the homogeneous interconnect structure includes a first region and a second region one above another, where the first region comprises a width which increases relative to height, and where the second region comprises a width which decreases relative to height.

### BACKGROUND

The present invention generally relates to semiconductor structures, and more particularly to low resistance semiconductor interconnect structures.

Back end of line (BEOL) is the portion of integrated circuit fabrication where the individual devices (transistors, capacitors, resisters, etc.) get interconnected with one or more metallization layers. The BEOL generally begins immediately above the front-end-of-line region which contains the devices themselves. In general, the BEOL includes contacts, insulating layers (dielectrics), metal levels, and bonding sites for chip-to-package connections.

### SUMMARY

According to an embodiment of the present invention, a semiconductor structure is provided. The semiconductor structure may include a homogeneous interconnect structure embedded in a dielectric layer, where the homogeneous interconnect structure includes a first region and a second region one above another, where the first region includes a width which increases relative to height, and where the second region includes a width which decreases relative to height.

According to another embodiment of the present invention, the structure according to paragraph [0003], further includes a barrier layer separating the homogeneous interconnect structure from the dielectric layer.

According to another embodiment of the present invention, the structure according to paragraph [0003], further includes a barrier layer separating the homogeneous interconnect structure from the dielectric layer, wherein the barrier layer includes at least two different materials.

According to another embodiment of the present invention, the structure according to paragraph [0003], further includes a barrier layer includes a first material and a second material, wherein the first material separates the first region of the homogeneous interconnect structure from the dielectric layer, and wherein the second material separates the second region of the homogeneous interconnect structure from the dielectric layer.

According to another embodiment of the present invention, where the dielectric layer includes at least two different dielectric materials.

According to another embodiment of the present invention, where the first region is substantially aligned with the second region.

According to another embodiment of the present invention, a semiconductor structure is provided. The semiconductor structure may include a homogeneous interconnect structure embedded in a dielectric layer, where the homogeneous interconnect structure includes a first region, a second region, and a third region one above another, where the first region includes a width which increases relative to height, where the second region includes a width which decreases relative to height, and where the third region includes a substantially uniform width relative to height.

According to another embodiment of the present invention, the structure according to paragraph [0009], further includes a barrier layer separating the homogeneous interconnect structure from the dielectric layer.

According to another embodiment of the present invention, the structure according to paragraph [0009], further includes a barrier layer separating the homogeneous interconnect structure from the dielectric layer, wherein the barrier layer includes at least two different materials.

According to another embodiment of the present invention, the structure according to paragraph [0009], further includes a barrier layer including a first material and a second material, wherein the first material separates the first region of the homogeneous interconnect structure from the dielectric layer, and wherein the second material separates both the second region and the third region of the homogeneous interconnect structure from the dielectric layer.

According to another embodiment of the present invention, where the dielectric layer includes at least two different dielectric materials.

According to another embodiment of the present invention, where the first region is substantially aligned with the second region, and wherein the second region is substantially aligned with the third region.

According to another embodiment of the present invention, where an average width of both the first region and the second region is greater than a width of the third region.

According to another embodiment of the present invention, a semiconductor structure is provided. The semiconductor structure may include homogeneous interconnect structures embedded in a dielectric layer with a pitch less than 30 nm, where the homogeneous interconnect structures each include a first region, a second region, and a third region one above another, where the first region includes a width which increases relative to height, where the second region includes a width which decreases relative to height, and where the third region includes a substantially uniform width relative to height.

According to another embodiment of the present invention, the structure according to paragraph [0016], further includes a barrier layer separating the homogeneous interconnect structure from the dielectric layer.

According to another embodiment of the present invention, the structure according to paragraph [0016], further includes a barrier layer separating the homogeneous interconnect structure from the dielectric layer, wherein the barrier layer includes at least two different materials.

According to another embodiment of the present invention, the structure according to paragraph [0016], further includes a barrier layer including a first material and a second material, wherein the first material separates the first region of each homogeneous interconnect structure from the dielectric layer, and wherein the second material separates both the second region and the third region of each homogeneous interconnect structure from the dielectric layer.

According to another embodiment of the present invention, where the dielectric layer includes at least two different dielectric materials.

According to another embodiment of the present invention, where the first region is substantially aligned with the second region, and wherein the second region is substantially aligned with the third region.

According to another embodiment of the present invention, where an average width of both the first region and the second region is greater than a width of the third region.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a cross-section view of a structure shown during an intermediate step of a method of fabricating a low resistance interconnect structure according to an embodiment of the invention;

FIG. 2 is a cross-section view of the structure after patterning the first dielectric layer according to an embodiment of the invention;

FIG. 3 is a cross-section view of the structure after filling the openings with a sacrificial material according to an embodiment of the invention;

FIG. 4 is a cross-section view of the structure after forming a second dielectric layer according to an embodiment of the invention;

FIG. 5 is a cross-section view of the structure after etching the second dielectric layer to produce a positive tapered profile according to an embodiment of the invention;

FIG. 6 is a cross-section view of the structure after removing the sacrificial material according to an embodiment of the invention;

FIG. 7 is a cross-section view of the structure after depositing a first barrier layer according to an embodiment of the invention;

FIG. 8 is a cross-section view of the structure after depositing a conductive material according to an embodiment of the invention;

FIG. 9 is a cross-section view of the structure after forming a second mask according to an embodiment of the invention;

FIG. 10 is a cross-section view of the structure after patterning the conductive material to produce a negative tapered profile according to an embodiment of the invention;

FIG. 11 is a cross-section view of the structure after removing the second mask according to an embodiment of the invention;

FIG. 12 is a cross-section view of the structure after forming a second barrier layer according to an embodiment of the invention;

FIG. 13 is a cross-section view of the structure after removing portions of the second barrier layer according to an embodiment of the invention; and

FIG. 14 is a cross-section view of the structure after depositing a third dielectric layer according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Advanced transistor structures have known advantages over conventional transistor structures in terms of density, performance, power consumption, and integration. However, fabricating the metal lines in the back-end-of-line (BEOL) has become increasingly difficult as the demand for space continues to increase with the advent of smaller technology nodes. More specifically, for example, it is particularly challenging to form tight pitched metal lines without consequentially increasing line resistance. Moreover, for BEOL pitch below 30 nm, R/C delay is growing unsustainably large and there is a need to fill minimum critical dimension (CD) lines with alternative metals other than copper, for example ruthenium, to achieve lower line resistance; however, doing so can result in dielectric line wiggling. Dielectric line wiggling describes a phenomenon in which straight metal lines are not relatively straight. Dielectric line wiggle occurs when stresses from the metal fill, specifically metals other than copper, physically distort the surrounding dielectric. Dielectric line wiggle is especially problematic in designs with relatively high aspect ratios and pitches less than 30 nm. Excessive wiggle can cause shorts, bridging, and unplanned breaks in the subsequently formed metal lines. For purposes of this description, and all embodiments described herein, typical line pitch is less than 30 nm.

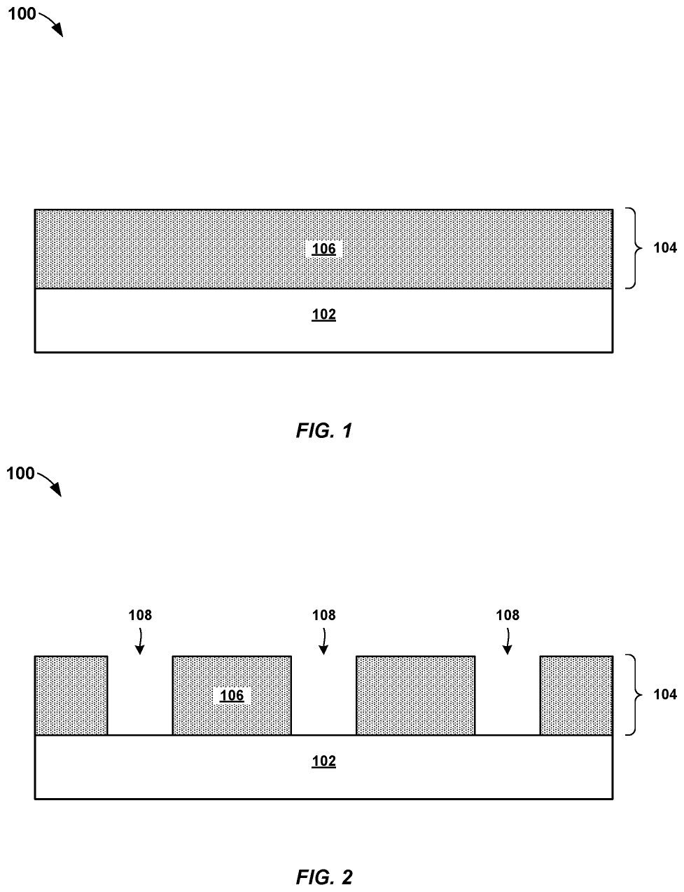

The present invention generally relates to semiconductor structures, and more particularly to low resistance semiconductor interconnect structures. More specifically, the interconnect structure and associated method disclosed herein enables a novel solution for providing a low resistance interconnect structure having a variable width relative to height. Exemplary embodiments of a low resistance interconnect structure having a variable width relative to height are described in detail below by referring to the accompanying drawings in FIGS. 1 to 14. Those skilled in the art will readily appreciate that the detailed description given herein with respect to these figures is for explanatory purposes as the invention extends beyond these limited embodiments.

Referring now to FIG. 1, a structure 100 is shown during an intermediate step of a method of fabricating a transistor structure according to an embodiment of the invention. The structure 100 may include a substrate 102 and a back-end-of-line metallization level 104 (metallization level 104), and sometime referred to as M ₓ level. The substrate 102 may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. In other embodiments, the substrate 102 may represent a device region, such as the front-end-of-line, or a prior metallization level in the back-end-of-line, such as Mₓ₋₁. In some cases, the substrate 102 may generally be referred to generally as a wafer.

At this stage of fabrication, the metallization level 104 begins with a first dielectric layer 106 formed directly on the substrate 102.

According to embodiments of the present invention, the first dielectric layer 106 may include any suitable dielectric material such as silicon based low-k dielectrics, or porous dielectrics. For example, the first dielectric layer 106 may organic polymer low-k dielectrics and SiCOH-based low-k dielectrics (such as SiCOH, SiCNOH) including selective low-k dielectric deposition.

In an embodiment, the first dielectric layer 106 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. In some embodiments, a planarization technique such as, for example, chemical mechanical planarization (CMP) and/or grinding is applied after deposition. In other embodiments, no polishing or griding of the first dielectric layer 106 is performed. In yet another embodiment, the first dielectric layer 106 may include a self-planarizing material such as a spin-on glass (SOG) or a spin-on low-κ dielectric material such as SiLK™. Doing so may avoid the need to perform a subsequent planarizing step.

The first dielectric layer 106 may have a typical thickness ranging from about 30 nm to about 100 nm and ranges there between, although a thickness less than 30 nm and greater than 100 nm are explicitly contemplated. It is noted the typical thickness of the first dielectric layer 106, at this stage of fabrication, is less than the typical thickness of a conventional dielectric layer deposited in the middle-of-line or back-end-of-line. For example, according to embodiments of the present invention, the typical thickness of the first dielectric layer 106, at this stage of fabrication, is approximately only 30% of the typical thickness of a conventional dielectric layer deposited in the middle-of-line or back-end-of-line. As such, for exemplary purposes only, if the typical thickness of a conventional dielectric layer deposited in the middle-of-line or back-end-of-line were approximately 100 nm, the typical thickness of the first dielectric layer 106, at this stage of fabrication, is approximately 30 nm.

Referring now to FIG. 2, a structure 100 is shown after patterning the first dielectric layer 106 according to an embodiment of the invention.

In general, patterning the first dielectric layer 106 includes forming a first mask (not shown) and removing portions of the first dielectric layer 106 not protected by the first mask according to known techniques. More specifically, the first mask is created by first depositing a photoresist material directly above the dielectric layer 106 and lithographically patterning the photoresist material to form the first mask. The photoresist material may be patterned by exposing the photoresist to a desired pattern of radiation and developing the exposed photoresist utilizing a conventional resist developer. The first mask or pattern in the photoresist may then be transferred to the dielectric layer 106 using one or more dry etching techniques. Suitable dry etching techniques may include, but are not limited to: reactive ion etching (RIE), ion beam etching, plasma etching, or laser ablation. In an embodiment, a RIE technique using, for example, a chlorine based etchant including BCl₃, CHCl₃, or Cl₂, may be used to transfer the first mask pattern into the underlying dielectric layer (106). After etching, the patterned photoresist (i.e. the first mask) is then removed by resist stripping. The first mask may include well known photoresist materials, for example, a soft mask, and could be either positive or negative in tone. Optionally, a non-contact or a hardmask may also be used.

Removing portions of the first dielectric layer 106 selective to the first mask creates openings 108 and exposes the underlying substrate 102. According to embodiments of the present invention, the openings 108 typically correspond to designed metal features, such as, metal features or metal lines in the middle-of-line or back-end-of-line. Similarly, according to embodiments of the present invention, the openings 108 would have a relatively small pitch, for example less than 30 nm, and a typical width of approximately 10 nm to approximately 18 nm.

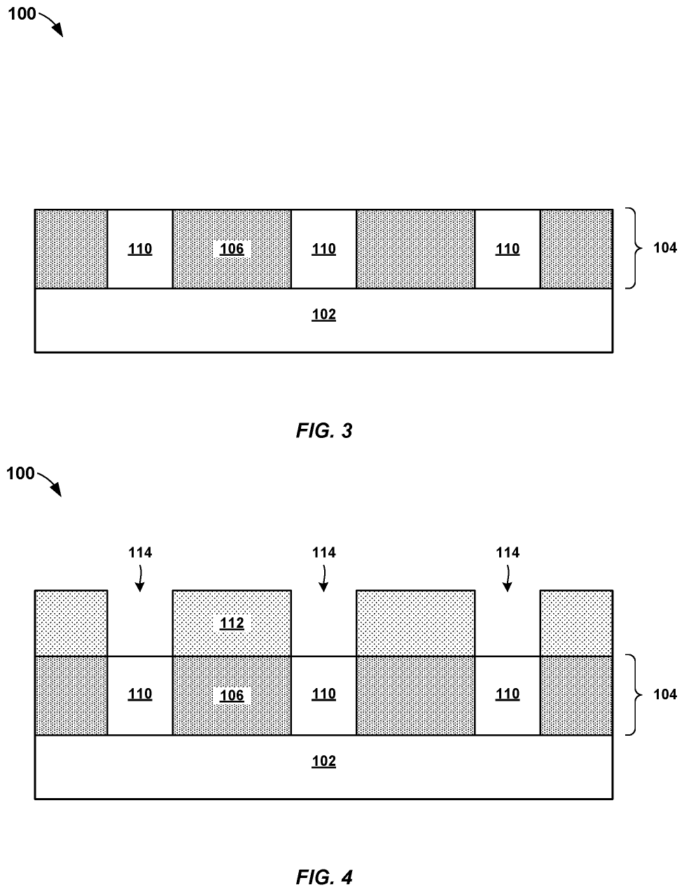

Referring now to FIG. 3, a structure 100 is shown after filling the openings 108 with a sacrificial material 110 according to an embodiment of the invention.

The openings 108 are filled, or substantially filled, with a sacrificial material 110 according to known techniques. According to embodiments of the present invention, the first dielectric layer 106 may include any suitable sacrificial material which is capable of being removed selective to at least the first dielectric layer 106. In an embodiment, the sacrificial material 110 is an organic planarization layer (OPL). Even more specifically, the sacrificial material 110 is a material which enables selective deposition of dielectrics during subsequent processing as discussed in greater detail below. In an embodiment, for example, the sacrificial material 110 can be an amorphous carbon layer. After depositing the sacrificial material 110, a chemical mechanical polishing technique may be applied to remove excess material of the sacrificial material 110. Polishing may continue until the first dielectric layer 106 is exposed, or until topmost surfaces of the sacrificial material 110 and the first dielectric layer 106 are flush, or substantially flush.

Referring now to FIG. 4, a structure 100 is shown after forming a second dielectric layer 112 according to an embodiment of the invention.

The second dielectric layer 112 is selectively deposited on the upper surface of the first dielectric layer 106 without being deposited on adjacent surfaces of the sacrificial material 110 according to known techniques. Doing so naturally creates trenches 114 in which the sacrificial material 110 remain exposed at a bottom thereof. As such, the second dielectric layer 112 will generally be self-aligned with the underlying dielectric layer, here the first dielectric layer 106; however, some lateral growth or lateral overlap is expected. In such cases, the second dielectric layer 112 may extend laterally beyond the interface between the first dielectric layer 106 and the sacrificial material 110. Such lateral overlap is expected to be negligible and thus is not depicted in the figures. Further, such lateral overlap is inconsequential and has no material effect on the embodiments described herein.

As described herein, selective deposition refers to a material being selectively deposited on surface A and not on surface B. The ability to selectively deposit semiconductor materials has enabled new integration and patterning schemes all while decreasing the number of manufacturing operations otherwise associated with conventional semiconductor manufacturing processes, as described above.

According to embodiments of the present invention, the second dielectric layer 112 may include any dielectric material compatible with known selective deposition techniques, such as, but not limited to, the exemplary materials listed above with respect to the first dielectric layer 106. In an embodiment, the second dielectric layer 112 may include the same or similar dielectric material as the first dielectric layer 106. In an alternative embodiment, the second dielectric layer 112 may include a different dielectric material as the first dielectric layer 106.

In at least one embodiment, selective deposition of the second dielectric layer 112 is accomplished by thermal ALD or CVD using self-assembled monolayers to block metal surfaces against dielectric deposition. In an embodiment, selective deposition of the second dielectric layer 112 can be performed with or without pretreatment of any adjacent or nearby metal surfaces.

The second dielectric layer 112 may have a typical thickness ranging from about 30 nm to about 100 nm and ranges there between, although a thickness less than 30 nm and greater than 100 nm are explicitly contemplated. Like the first dielectric layer 106, it is noted the typical thickness of the second dielectric layer 112, at this stage of fabrication, is less than the typical thickness of a conventional dielectric layer deposited in the middle-of-line or back-end-of-line. For example, according to embodiments of the present invention, the typical thickness of the second dielectric layer 112, at this stage of fabrication, is approximately only 30% of the typical thickness of a conventional dielectric layer deposited in the middle-of-line or back-end-of-line. As such, for exemplary purposes only, if the typical thickness of a conventional dielectric layer deposited in the middle-of-line or back-end-of-line were approximately 100 nm, the typical thickness of the second dielectric layer 112, at this stage of fabrication, is approximately 30 nm.

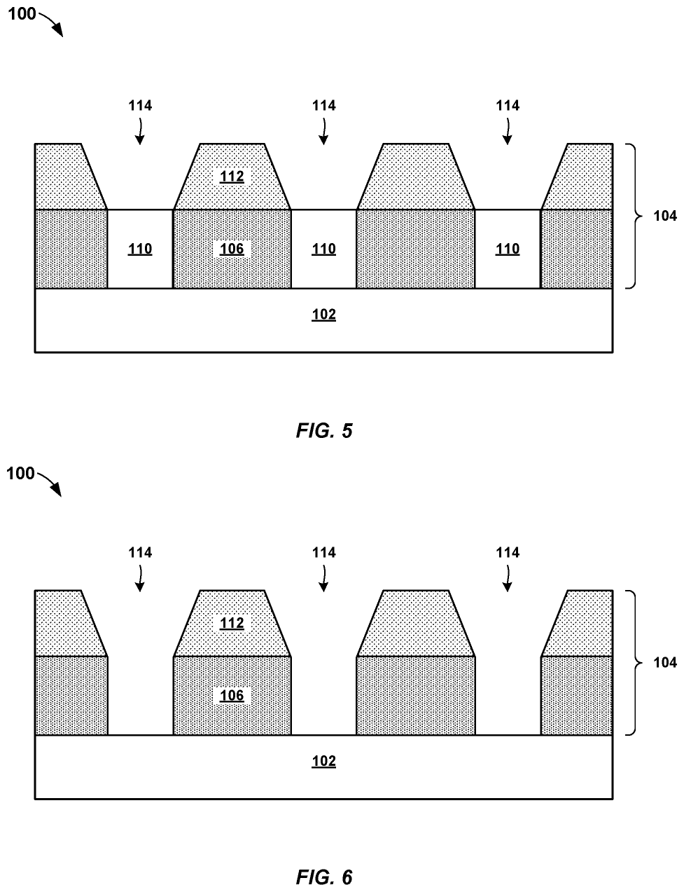

Referring now to FIG. 5, a structure 100 is shown after etching the second dielectric layer 112 to produce a positive tapered profile according to an embodiment of the invention.

An etching technique is applied to generally enlarge the trenches 114, as illustrated and according to known techniques. Specifically, a directional or isotropic dry etching technique, such as reactive ion etching, is used to etch exposed portions of the second dielectric layer 112 and further expand or enlarge the trenches 114. The object of this directional etching technique is to increase the size, or width, of the trenches 114. More specifically, the directional etching technique is applied at a very specific angle to create a very specific positive tapered profile in which a lateral width at a bottom of the trench is smaller than a lateral width at a top of the trench 114, as illustrated. Said differently, a sidewall angle of the positive tapered profile may range from approximately 30 degrees to approximately 50. The desired angle of the positive tapered profile is carefully chosen to maximize a width at the top of the trench while also maintaining an acceptable distance between adjacent trenches 114. In some cases, the directional etching will also simultaneously reduce the overall height of the second dielectric layer 112.

Suitable directional etching techniques may include, but are not limited to: reactive ion etching (RIE), ion beam etching, plasma etching, or laser ablation. In an embodiment, a RIE technique using, for example, with or without including argon ion species, may be used to enlarge the trenches 114 as described above. In an alternative embodiment, an ion beam etching technique using, for example, at fixed ion beam angle corresponding to the desired taper angle of the structure, may be used to enlarge the trenches 114 as described above. In all cases, the directional etching technique shall be chosen and tailored to the specific dielectric material of the second dielectric layer 106 in order to produce the desired positive tapered profile.

Further, although the directional etching technique is not particularly selective to the sacrificial material 110 or even the first dielectric layer 106, the process window and direction should be carefully controlled such that the sacrificial material 110 and the first dielectric layer 106 remain substantially as they were prior to etching.

Referring now to FIG. 6, a structure 100 is shown after removing the sacrificial material 110 according to an embodiment of the invention.

Next, the sacrificial material 110 is entirely removed according to known techniques. Specifically, the sacrificial material 110 is removed selective to both the first dielectric layer 106 and the second dielectric layer 112, as illustrated. For example, the sacrificial material 110 is removed selective to both the first dielectric layer 106 and the second dielectric layer 112 using known etching techniques suitable to remove OPL selective to silicon oxides or silicon nitrides. According to embodiments of the present invention, the sacrificial material 110 is entirely removed using an ashing technique or a wet clean technique. After removal, the substrate 102 is once again exposed, as illustrated.

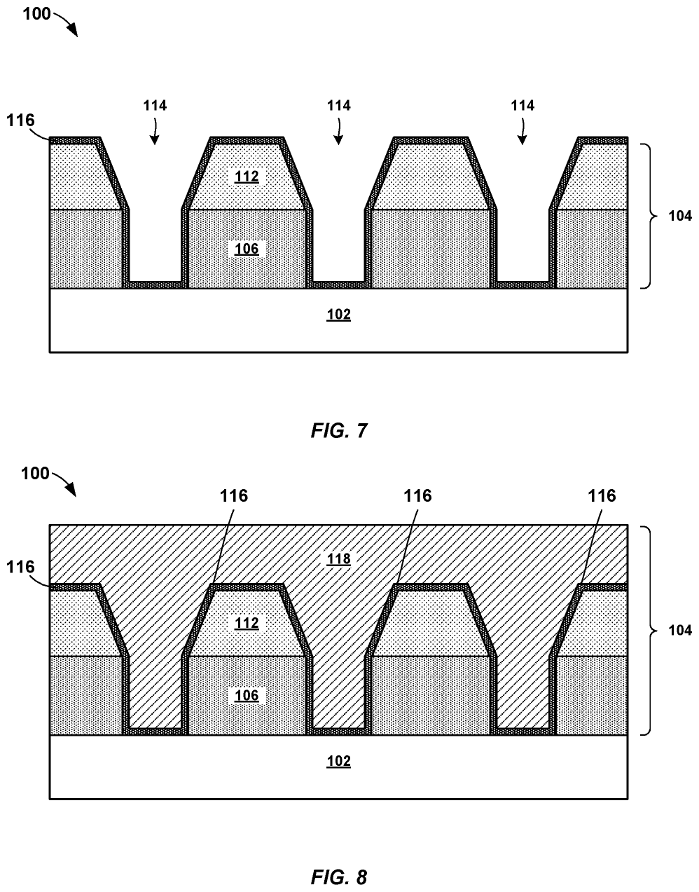

Referring now to FIG. 7, a structure 100 is shown after depositing a first barrier layer 116 according to an embodiment of the invention.

The first barrier layer 116, or nucleation layer, is formed by conformally depositing a barrier material over the structure 100 according to known techniques. Specifically, the barrier material is conformally deposited on a top and tapered sidewalls of the second dielectric layer 112, exposed sidewalls of the first dielectric layer 106, and exposed surfaces of the substrate 102, as illustrated. As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

As well known by persons having skill in the art, the first barrier layer 116 is typically applied to create a diffusion break between sidewall portions of the surrounding dielectrics (106, 112). As such, the first barrier layer 116 would be designed to prevent diffusion of any subsequently deposited conductive material into the surrounding dielectrics (106, 112).

According to embodiments of the present invention the first barrier layer 116 is composed of any known suitable barrier materials, for example, metal nitrides. In an embodiment, the first barrier layer 116 is titanium nitride (TiN), tungsten nitride (WN), tantalum nitride (TaN) Boron Carbon doped Tungsten (WBC), or some combination thereof. In an embodiment, the first barrier layer 116 includes multiple layers for example a tantalum layer and a tantalum nitride layer. In another embodiment, the first barrier layer 116 includes a single layer of tungsten nitride (WN). In yet another embodiment, the first barrier layer 116 includes a single layer of titanium tungsten nitride (TiWN).

In an embodiment, the first barrier layer 116 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, the first barrier layer 116 may have a thickness sufficient to achieve desired barrier properties as is well known to persons having skill in the art. For example, the first barrier layer 116 may have a typical thickness ranging from about 1 nm to about 4 nm and ranges there between, although a thickness less than 1 nm and greater than 4 nm are explicitly contemplated.

Referring now to FIG. 8, a structure 100 is shown after depositing a conductive material 118 according to an embodiment of the invention.

The conductive material 118 is blanket deposited on the structure 100 filling the trenches 114 according to known techniques. More specifically, according to an embodiment, the conductive material 118 is blanket deposited directly on exposed surfaces of the first barrier layer 116, as illustrated.

According to embodiments of the present invention the conductive material 118 may include any suitable conductive interconnect materials such as molybdenum, tungsten, rhodium, iridium, copper, or alloys or combinations thereof. In an embodiment, for example, the conductive material 118 is molybdenum.

In an embodiment, the conductive material 118 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, deposition of the conductive material 118 continues until the trenches 114 are completely filled and well in excess of uppermost surface of the structure 100, as illustrated. For example, the conductive material 118 may have a typical thickness ranging from about 60 nm to about 300 nm and ranges there between, although a thickness less than 60 nm and greater than 300 nm are explicitly contemplated.

It is noted, the trenches 114 (FIG. 7) have relatively low aspect ratios which permit filling with the conductive material 118 with little or no voids. For example, the aspect ratios of the trenches 114 (FIG. 7) may be approximately 2:1, height to average width. Further, the relatively low aspect ratio of the trenches 114 (FIG. 7) additionally significantly decreases the danger of dielectric line wiggle.

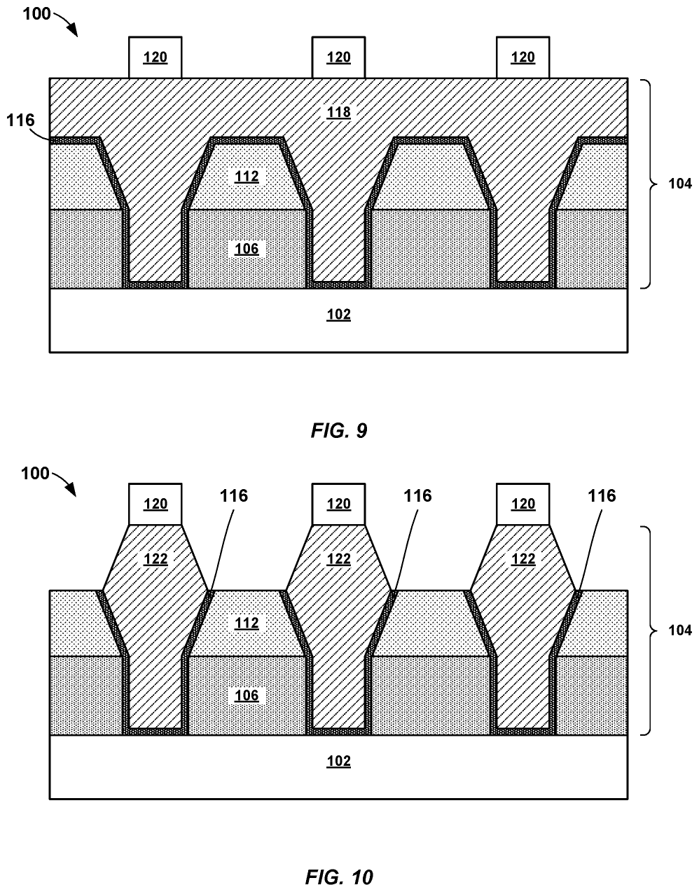

Referring now to FIG. 9, a structure 100 is shown after forming a second mask 120 according to an embodiment of the invention.

The second mask 120 is formed above the conductive material 118 according to known techniques. More specifically, the second mask 120 is created by first depositing a photoresist material directly above the conductive material 118 and lithographically patterning the photoresist material to form the second mask 120. The photoresist material may be patterned by exposing the photoresist to a desired pattern of radiation and developing the exposed photoresist utilizing a conventional resist developer.

According to embodiments of the present invention, the second mask 120 typically corresponds to designed metal features, such as, that same metal features or metal lines in the middle-of-line or back-end-of-line corresponding to the openings 108 (FIG. 2). More specifically, the size and location of the second mask 120 corresponds and aligns with the openings 108 (FIG. 2) and trenches 114 (FIG. 7), now filled with the conductive material 118. It is preferred that the second mask 120 be aligned with the openings 108 (FIG. 2) and trenches 114 (FIG. 7); however, such alignment is not mandatory and some tolerance (1-2 nm) in alignment accuracy is acceptable.

Referring now to FIG. 10, a structure 100 is shown after patterning the conductive material 118 to produce a negative tapered profile according to an embodiment of the invention.

An etching technique is applied to generally remove portions of the conductive material 118 according to known techniques. Specifically, a suitable directional etching technique is used to etch exposed portions of the conductive material 118 and expose topmost surfaces of the second dielectric layer 112. The object of this directional etching technique is to form individual interconnect structures 122 having a negative tapered profile. More specifically, the directional etching technique is applied at a very specific angle to create a very specific negative tapered profile in portions of the conductive material 118 remaining above the second dielectric layer 112. Specifically, the portions of the conductive material 118 remaining above the second dielectric layer 112 with a negative tapered profile have a lateral width at, or about, the topmost surface of the second dielectric layer 112 that is larger than a lateral width at a topmost surface of the conductive material 118, as illustrated. Said differently, a sidewall angle of the negative tapered profile may range from approximately −30 degrees to approximately −50 degrees. Like the positive tapered profile described above, the desired angle of the negative tapered profile is carefully chosen to maximize a width at, or about, a middle of the individual interconnect structures 122 while also maintaining an acceptable distance between adjacent remaining portions of the individual interconnect structures 122.

Suitable directional etching techniques may include, but are not limited to: reactive ion etching (RIE), ion beam etching, plasma etching, or laser ablation. In an embodiment, a RIE technique using, for example, with or without including argon ion species, may be used to remove portions of the conductive material 118 and form the individual interconnect structures 122 as described above. In an alternative embodiment, an ion beam etching technique using, for example, at fixed ion beam angle corresponding to the desired taper angle of the structure, may be used to remove portions of the conductive material 118 and form the individual interconnect structures 122 as described above. In all cases, the directional etching technique shall be chosen and tailored to the specific material of the conductive material 118 in order to produce the desired negative tapered profile.

Etching is also designed to remove substantially horizontal portions of the first barrier layer 116, as illustrated. After etching, topmost surfaces of the second dielectric layer 112 are exposed, as illustrated.

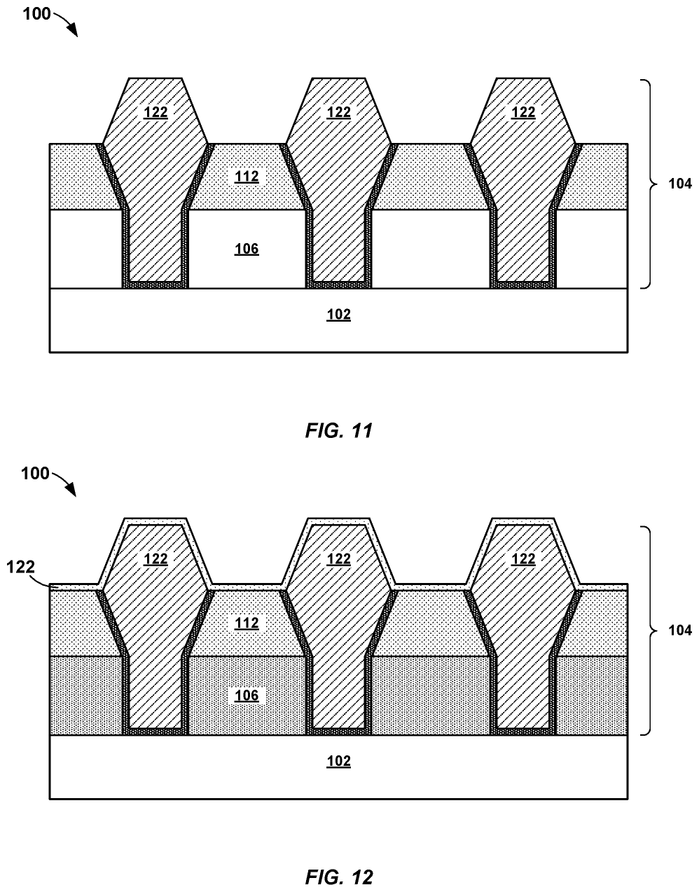

Referring now to FIG. 11, a structure 100 is shown after removing the second mask 120 according to an embodiment of the invention. The second mask 120 is removed according to known techniques. For example, after etching the conductive material 118 the second mask 120 is then removed by resist stripping. For purposes of the present description, the second mask 120 is the same, or substantially similar, as the first mask previously described.

Referring now to FIG. 12, a structure 100 is shown after forming a second barrier layer 124 according to an embodiment of the invention.

The second barrier layer 124, or nucleation layer, is formed by conformally depositing a barrier material over the structure 100 according to known techniques. Specifically, the barrier material is conformally deposited on a top and tapered sidewalls of the conductive material 118 and exposed topmost surfaces of the second dielectric layer 112, as illustrated.

As well known by persons having skill in the art, the second barrier layer 124 is typically applied to create a diffusion break between sidewall portions of subsequently formed dielectrics. As such, the second barrier layer 124 would be designed to prevent diffusion of the conductive material of the individual interconnect structures 122 into the subsequently formed dielectrics. According to embodiments of the present invention the second barrier layer 124 is composed of any known suitable barrier materials, for example, metal nitrides. In an embodiment, the second barrier layer 124 is titanium nitride (TiN), tungsten nitride (WN), tantalum nitride (TaN) Boron Carbon doped Tungsten (WBC), or some combination thereof. In an embodiment, the second barrier layer 124 includes multiple layers for example a tantalum layer and a tantalum nitride layer. In another embodiment, the second barrier layer 124 includes a single layer of tungsten nitride (WN). In yet another embodiment, the first barrier layer 116 includes a single layer of titanium tungsten nitride (TiWN). Further, the second barrier layer 124 maybe the same or different composition as the first barrier layer 116. In all cases, the barrier layers (116, 124) would preferably be chosen based on the specific surrounding materials of the dielectric layers (106, 112, 126) and the conductive material 118.

In an embodiment, the second barrier layer 124 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In general, the second barrier layer 124 may have a thickness sufficient to achieve desired barrier properties as is well known to persons having skill in the art. For example, the second barrier layer 124 may have a typical thickness ranging from about 1 nm to about 4 nm and ranges there between, although a thickness less than 1 nm and greater than 4 nm are explicitly contemplated.

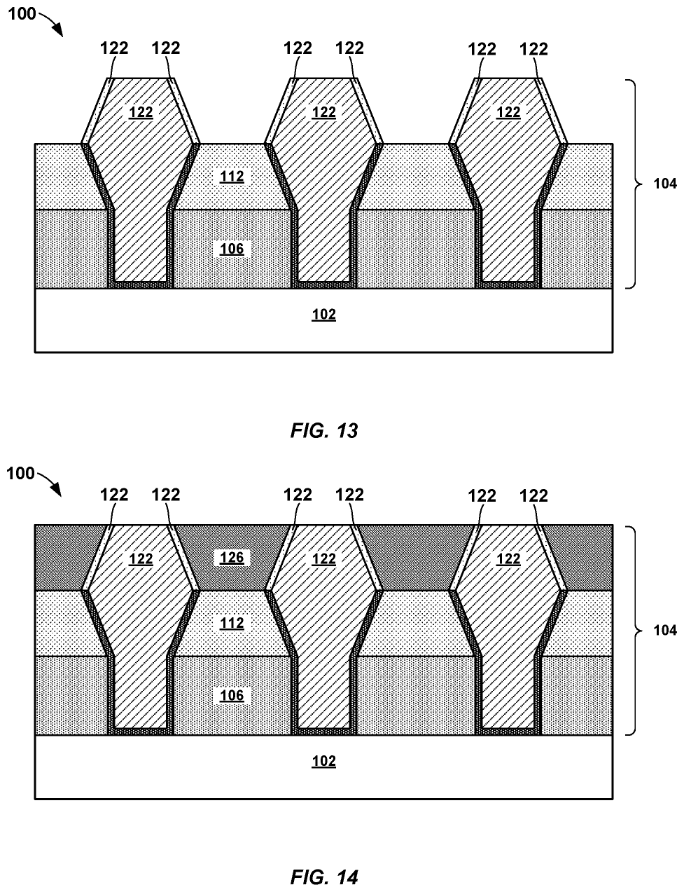

Referring now to FIG. 13, a structure 100 is shown after removing portions of the second barrier layer 124 according to an embodiment of the invention.

An etching technique is applied to remove horizontal portions of the second barrier layer 124 according to known techniques. Specifically, one or more dry etching techniques is used to remove horizontal portions of the second barrier layer 124, as illustrated. Suitable dry etching techniques may include, but are not limited to: reactive ion etching (RIE), ion beam etching, plasma etching, or laser ablation. In all cases, the dry etching technique shall cause portions of the second barrier layer 124 to remain on the negative tapered sidewalls of the individual interconnect structures 122.

Referring now to FIG. 14, a structure 100 is shown after depositing a third dielectric layer 126 according to an embodiment of the invention.

The third dielectric layer 126 is deposited on the upper surface of the second dielectric layer 112 according to known techniques. According to embodiments of the present invention, the third dielectric layer 126 may include any dielectric material compatible with known deposition techniques, such as, but not limited to, the exemplary materials listed above with respect to the first dielectric layer 106. In an embodiment, the third dielectric layer 126 may include the same or similar dielectric material as the first dielectric layer 106, the second dielectric layer 112, or both. In an alternative embodiment, the third dielectric layer may include a different dielectric material as the second dielectric layer 112. In yet another embodiment, both the first dielectric layer 106 and the second dielectric layer 112 are made from a first material and the third dielectric layer 126 is made from a second material. In such cases, the respective barrier layers would be chosen based on their compatibility and function with the first material and the second material.

In an embodiment, the third dielectric layer 126 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering. In some embodiments, a planarization technique such as, for example, chemical mechanical planarization (CMP) and/or grinding is applied after deposition. In other embodiments, no polishing or griding of the third dielectric layer 126 is performed. In yet another embodiment, the third dielectric layer 126 may include a self-planarizing material such as a spin-on glass (SOG) or a spin-on low-κ dielectric material such as SiLK™. Doing so may avoid the need to perform a subsequent planarizing step.

The third dielectric layer 126 may have a typical thickness ranging from about 30 nm to about 100 nm and ranges there between, although a thickness less than 30 nm and greater than 100 nm are explicitly contemplated. It is noted the typical thickness of the is less than the typical thickness of a conventional dielectric layer deposited in the middle-of-line or back-end-of-line. For example, according to embodiments of the present invention, the typical thickness of the third dielectric layer 126 is approximately only 30% of the typical thickness of a conventional dielectric layer deposited in the middle-of-line or back-end-of-line. As such, for exemplary purposes only, if the typical thickness of a conventional dielectric layer deposited in the middle-of-line or back-end-of-line were approximately 100 nm, the typical thickness of the first dielectric layer 106, at this stage of fabrication, is approximately 30 nm. As such, the combined height or thickness of the first dielectric layer 106, the second dielectric layer 112, and the third dielectric layer 126 is approximately equal to the typical thickness of a conventional dielectric layer deposited in the middle-of-line or back-end-of-line. Each of the first dielectric layer 106, the second dielectric layer 112, and the third dielectric layer 126 do not have to have to be equal thicknesses. For example, it is explicitly contemplated for one of the dielectric layers, such as the first dielectric layer 106, to have a thickness less than either the second dielectric layer 112 or the third dielectric layer 124. Or in another example, either the second dielectric layer 112 or the third dielectric layer 124 has a thickness less than a thickness of the first dielectric layer 106. Finally, the second dielectric layer 112 may be thicker than the third dielectric layer 124, or vice versa.

In sum, for purposes of this description the structure 100 illustrated in the figures, and described herein, includes multiple low resistance semiconductor interconnect structures 122 positioned adjacent, or next, to one another, and manufactured in a process flow. Embodiments of the present invention, and the detailed description provided above, are directed primarily at the physical shape or profile of the individual interconnect structures. For example, each low resistance semiconductor interconnect structure represented by the structure 100 has a width which both increases and decreases relative to height. Said differently, each low resistance semiconductor interconnect structure represented by the structure 100 is laterally wider in a middle portion as compared to a top or a bottom. As such, the low resistance semiconductor interconnect structures each have a profile with both positive tapered sidewalls and negative tapered sidewalls.

As illustrated in FIG. 14, the low resistance semiconductor interconnect structures represented by the structure 100 have some distinctive notable features. For example, the interconnect structures are embedded in a dielectric and fabricated with only a single metal deposition resulting in a homogeneous, or congruent, interconnect structure without unnecessary boundaries or interfaces which are otherwise prone to oxidation and increased resistance. Further, at the time of metal deposition (FIG. 8) the trenches (114) have a relatively low aspect ratio which enables (a) complete filling of the trench and low risk of void creation, and (b) greatly reduces the possibility for dielectric line wiggle.

Additionally, the critical dimension (width) of the final interconnect structures is relatively larger than conventional structures thereby decreasing line resistance. In sum, the critical dimension the interconnect structures represented by the structure 100 enable fabrication of low resistance structures in high densities without the conventional concerns of shorting, bridging or breaks caused by dielectric line wiggle.

To elaborate on the specific features of the interconnect structures disclosed herein reference will be made to different regions of the interconnect structures, for example a first region, a second region, and a third region. The first region generally refers to a portion of the interconnect structure aligned with the third dielectric layer 126, the second region generally refers to a portion of the interconnect structure aligned with the second dielectric layer 112, and the third region generally refers to a portion of the interconnect structure aligned with the first dielectric layer 106.

With continued reference to FIG. 14, the first region, the second region and the third regions are arranged one above another. Further, the first region has a width which increases relative to height, the second region has a width which decreases relative to height, and the third region has a substantially uniform width relative to height. In general, the barrier layer (116, 122) separates the interconnect structure from the dielectric layers (106, 112, 126). Specifically, the barrier layer may include a first barrier layer (116) separating the first region of the interconnect structure from the dielectric layer (126), and a second barrier layer (124) separating both the second region and the third region of the interconnect structure from the dielectric layer (106, 112). In some embodiments, as previously described above, the barrier layer (116, 122) can include at least two different materials. In all cases, an average width of both the first region and the second region is greater than a width of the third region.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a homogeneous interconnect structure embedded in a dielectric layer, wherein the homogeneous interconnect structure comprises a first region and a second region one above another,
wherein the first region comprises a width which increases relative to height, and
wherein the second region comprises a width which decreases relative to height.

2. The semiconductor structure according to claim 1, further comprising:
a barrier layer separating the homogeneous interconnect structure from the dielectric layer.

3. The semiconductor structure according to claim 1, further comprising:
a barrier layer separating the homogeneous interconnect structure from the dielectric layer, wherein the barrier layer comprises at least two different materials.

4. The semiconductor structure according to claim 1, further comprising:
a barrier layer comprising a first material and a second material, wherein the first material separates the first region of the homogeneous interconnect structure from the dielectric layer, and
wherein the second material separates the second region of the homogeneous interconnect structure from the dielectric layer.

5. The semiconductor structure according to claim 1, wherein the dielectric layer comprises at least two different dielectric materials.

6. The semiconductor structure according to claim 1, wherein the first region is substantially aligned with the second region.

7. A semiconductor structure comprising:
a homogeneous interconnect structure embedded in a dielectric layer, wherein the homogeneous interconnect structure comprises a first region, a second region, and a third region one above another,
wherein the first region comprises a width which increases relative to height,
wherein the second region comprises a width which decreases relative to height, and
wherein the third region comprises a substantially uniform width relative to height.

8. The semiconductor structure according to claim 7, further comprising:
a barrier layer separating the homogeneous interconnect structure from the dielectric layer.

9. The semiconductor structure according to claim 7, further comprising:
a barrier layer separating the homogeneous interconnect structure from the dielectric layer, wherein the barrier layer comprises at least two different materials.

10. The semiconductor structure according to claim 7, further comprising:
a barrier layer comprising a first material and a second material, wherein the first material separates the first region of the homogeneous interconnect structure from the dielectric layer, and wherein the second material separates both the second region and the third region of the homogeneous interconnect structure from the dielectric layer.

11. The semiconductor structure according to claim 7, wherein the dielectric layer comprises at least two different dielectric materials.

12. The semiconductor structure according to claim 7, wherein the first region is substantially aligned with the second region, and wherein the second region is substantially aligned with the third region.

13. The semiconductor structure according to claim 7, wherein an average width of both the first region and the second region is greater than a width of the third region.

14. A semiconductor structure comprising:
homogeneous interconnect structures embedded in a dielectric layer with a pitch less than 30 nm, wherein the homogeneous interconnect structures each comprise a first region, a second region, and a third region one above another,
wherein the first region comprises a width which increases relative to height,
wherein the second region comprises a width which decreases relative to height, and
wherein the third region comprises a substantially uniform width relative to height.

15. The semiconductor structure according to claim 14, further comprising:
a barrier layer separating the homogeneous interconnect structure from the dielectric layer.

16. The structure according to claim 14, further comprising:
a barrier layer separating the homogeneous interconnect structure from the dielectric layer, wherein the barrier layer comprises at least two different materials.

17. The structure according to claim 14, further comprising:
a barrier layer comprising a first material and a second material, wherein the first material separates the first region of each homogeneous interconnect structure from the dielectric layer, and wherein the second material separates both the second region and the third region of each homogeneous interconnect structure from the dielectric layer.

18. The structure according to claim 14, wherein the dielectric layer comprises at least two different dielectric materials.

19. The structure according to claim 14, wherein the first region is substantially aligned with the second region, and wherein the second region is substantially aligned with the third region.

20. The structure according to claim 14, wherein an average width of both the first region and the second region is greater than a width of the third region.
